(19) United States
(12) Patent Application Publication
(10) Pub. No.: US 2025/0125194 A1
(43) Pub. Date: Apr. 17, 2025

(54) IMPROVED SURFACE PRE-TREATMENT FOR SEMICONDUCTOR DEVICE BONDING STRUCTURES AND METHODS OF FORMING THE SAME

(71) Applicant: Taiwan Semiconductor Manufacturing Company Limited, Hsinchu (TW)

(72) Inventors: Amram Eitan, Hsinchu (TW); Chin-Fu Kao, Taipei (TW)

(21) Appl. No.: 18/484,493

(22) Filed: Oct. 11, 2023

(51) Int. Cl. H01L 21/768; H01L 21/02; H01L 21/67

(52) U.S. Cl. CPC H01L 21/76829; H01L 21/02126; H01L 21/67138; H01L 21/76832; H01L 21/76898

(57) ABSTRACT

An embodiment semiconductor structure may include a first component having first electrical bonding structures formed within a first dielectric layer, a second component having second electrical bonding structures formed with a second dielectric layer, and an organic base layer formed between the first dielectric layer and the second dielectric layer. The organic base layer may include carbon chain structures such that the first dielectric layer is bonded to the second dielectric layer with bonds formed between the first dielectric layer, the organic base layer, and the second dielectric layer. The carbon chain structures may be characterized by a carbon number that is between 10 and 1000 and a hydrogen to carbon ratio H/C that is greater than 2 such that the organic base layer has a thickness that is 0.5 nm to 30 nm. The carbon chain structures may include functional groups that form bonds between the carbon chain structures.

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers over a semiconductor substrate, and patterning the various material layers using lithography and etching to form circuit components and elements thereon. Dozens or hundreds of integrated circuits are typically manufactured on a single semiconductor wafer, and individual dies on the wafer are singulated by sawing between the integrated circuits along scribe lines. The individual dies are typically packaged separately, in multi-chip modules, or in other types of packaging, for example.

As semiconductor packages have become more complex, package sizes have tended to become larger to accommodate greater numbers of integrated circuits and/or dies per package. These larger and more complex semiconductor packages have created challenges in making effective and reliable interconnections among various components of the semiconductor package. As such, there is an ongoing need for improvements to semiconductor package designs with an emphasis on reducing interconnect lengths to thereby reduce ohmic loss, heat generation, and signal delay. There is also an ongoing need for improvement in die-to-die bonding structures and methods.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a chip assembly structure including a first semiconductor die and a second semiconductor die illustrating a first bonding configuration, according to various embodiments.

FIG. 2 is a vertical cross-sectional view of a chip assembly structure including a first semiconductor die and a second semiconductor die illustrating further bonding configurations, according to various embodiments.

FIG. 3A is a vertical cross-sectional view of an intermediate structure including a first dielectric layer and a second dielectric layer in a pre-bonding configuration prior to formation of direct dielectric-to-dielectric bonds.

FIG. 3B is a vertical cross-sectional view of a further intermediate structure including the first dielectric layer and the second dielectric layer of FIG. 3A in a bonding configuration during formation of direct dielectric-to-dielectric bonds.

FIG. 3C is a vertical cross-sectional view of a bonded structure after formation of direct dielectric-to-dielectric bonds between the first dielectric layer and the second dielectric layer.

FIG. 4 is a vertical cross-sectional view of a semiconductor structure having improved dielectric-to-dielectric bonding structures, according to various embodiments.

FIG. 5A is a vertical cross-sectional view of an intermediate structure including a first dielectric layer and a second dielectric layer in a pre-bonding configuration prior to formation of direct dielectric-to-dielectric bonds using an organic base film, according to various embodiments.

FIG. 5B is a vertical cross-sectional view of a bonded structure after formation of direct dielectric-to-dielectric bonds between the first dielectric layer and the second dielectric layer of FIG. 5A, according to various embodiments.

FIG. 5C illustrates an example chemical reaction that may occur between functional groups attached to carbon chain structures, according to various embodiments.

FIG. 6A illustrates an example carbon chain structure having a hydrogen/carbon ratio that is greater than 2, according to various embodiments.

FIG. 6B illustrates a comparative example cyclic carbon molecule having a hydrogen/carbon ratio that is approximately equal to 1, according various embodiments.

FIG. 7 is a three-dimensional perspective view of a plasma jet apparatus that may be used to deposit an organic base film on a surface of a dielectric layer, according to various embodiments.

FIG. 8A is a vertical cross-sectional view of an intermediate structure that may be used in the formation of a semiconductor structure, according to various embodiments.

FIG. 8B is a vertical cross-sectional view of a further intermediate structure that may be used in the formation of a semiconductor structure, according to various embodiments.

FIG. 8C is a vertical cross-sectional view of a further intermediate structure that may be used in the formation of a semiconductor structure, according to various embodiments.

FIG. 8D is a vertical cross-sectional view of a further intermediate structure that may be used in the formation of a semiconductor structure, according to various embodiments.

FIG. 9 is a flowchart illustrating operations of a method of forming a semiconductor structure, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies (i.e., “chips”) may be mounted onto a common substrate. The semiconductor package typically includes a housing that encloses the IC dies to protect the IC dies from damage. The housing may also provide heat dissipation from the semiconductor package. An increase to the complexity of semiconductor package devices may give rise to challenges related to the need to reduce ohmic loss to thereby reduce heat generation and signal propagation delay. To mitigate such issues, new designs are desired to reduce interconnect lengths by increasing package integration. There is also an ongoing need for improvement in die-to-die bonding structures and methods. One promising method of bonding package components includes the formation of hybrid bonding structures that include direct metal-to-metal bonds between electrically conducting bonding structures and direct dielectric-to-dielectric bonding between dielectric interfaces.

Various embodiments disclosed herein may be advantageous by providing an organic base layer that may be used in a modified dielectric-to-dielectric bonding process. The organic base layer may generate dielectric-to-dielectric bonds having increased strength relative to dielectric-to-dielectric bonds generated without the use of the organic base layer. The organic base layer may also allow dielectric-to-dielectric bonds to be formed at an annealing temperature that may be considerably lower relative to annealing temperatures of processes that do not include the organic base layer. The organic base layer may act to reduce internal stresses between bonded dielectric layers and may also allow surfaces to be bonded that have a greater degree of roughness than may be tolerated using alternative dielectric-to-dielectric bonding processes.

An embodiment semiconductor structure may include a first component having first electrical bonding structures formed within a first dielectric layer, a second component having second electrical bonding structures formed within a second dielectric layer, and an organic base layer formed between the first dielectric layer and the second dielectric layer. The organic base layer may include carbon chain structures such that the first dielectric layer is bonded to the second dielectric layer with bonds formed between the first dielectric layer, the second dielectric layer, and the organic base layer. The carbon chain structures may be characterized by a carbon number that is between 10 and 1000 and a hydrogen to carbon ratio H/C that is greater than 2 such that the organic base layer has a thickness that is 0.5 nm to 30 nm. The carbon chain structures may include functional groups that form bonds between the carbon chain structures.

A further semiconductor structure may include a first component including a first dielectric layer and a first organic base layer, including first carbon chain structures, formed on a first surface of the first dielectric layer. The first carbon chain structures may each include a first proximal end bonded to the first dielectric layer with first carbon-silicon bonds and a first distal end including a first organic functional group. The semiconductor structure may further include a second component including a second dielectric layer and a second organic base layer, including second carbon chain structures, formed on a second surface of the second dielectric layer. The second carbon chain structures may each include a second proximal end bonded to the second dielectric layer with second carbon-silicon bonds and a second distal end including a second organic functional group. The first component and the second component may be bonded to one another through covalent bonds formed between the first organic functional group and the second organic functional group.

An embodiment method of forming a semiconductor structure may include providing a first component including a first dielectric layer, providing a second component including a second dielectric layer, depositing a first organic base layer including first carbon chain structures on a first surface of the first dielectric layer, and depositing a second organic base layer including second carbon chain structures on a second surface of the second dielectric layer. The method may further include placing the first component and the second component within proximity to one another such that the first surface is facing the second surface. In some embodiments, the first surface may be parallel to the second surface. The method may further include bonding the first component to the second component by forming covalent bonds between the first carbon chain structures and the second carbon chain structures to thereby form the semiconductor structure.

Various embodiment structures and methods disclosed herein may be used to form a chip assembly structure in which various circuits (e.g., a memory array and a peripheral circuit controlling operation of the memory array) may be implemented in different semiconductor dies. Embodiment semiconductor dies may be formed to have certain components that may be formed in a front-end-of-line (FEOL) process that generates circuit elements (e.g., CMOS logic circuits) in or on a semiconductor substrate in addition to other circuit components (e.g., electrical interconnect structures formed with dielectric layers) formed in a back-end-of-line (BEOL) process.

As used herein, a “back-end-of-line” component or a “BEOL” component refers to any component that is formed at a contact level or at a metal interconnect level. A “metal interconnect level” refers to a level through which a metal interconnect structure, such as a metal line or a metal via structure, extends vertically. As used herein, a “front-end-of-line” component or an “FEOL” component refers to any component that is formed prior to formation of any contact level structure, if followed by formation of contact level structures, or without formation of any contact level structure or any metal interconnect structure (i.e., not followed by formation of any contact level structure or any metal interconnect structure).

In some embodiments, a chip assembly structure may include a semiconductor die stack that includes two or more double-sided semiconductor dies, each having a central portion (formed in a FEOL process) disposed between a front-side interconnect structure and a back side interconnect structure (formed in respective BEOL processes). For example, a die stack may include a first double-sided semiconductor die and a second double-sided semiconductor die. The first semiconductor die may include a first front-side interconnect structure and a first back-side interconnect structure, and the second semiconductor die may include a second front-side interconnect structure and a second back-side interconnect structure.

The first semiconductor die and the second semiconductor die may be electrically connected to one another by electrically connecting the first back-side interconnect structure of the first semiconductor die to the second front-side interconnect structure of the second semiconductor die. In other embodiments, a chip assembly structure may include a semiconductor die stack that includes two or more single-sided dies having a back-side FEOL portion and a front-side BEOL portion. The back-side FEOL portion may include electrical contact structures formed as through-substrate vias and the front-side BEOL portion may include interconnect structures formed in a dielectric material.

In various embodiments, a first semiconductor die and a second semiconductor die may be integrated into a chip assembly structure using a die-to-die connection, which may be implemented using a hybrid bonding process. The hybrid bonding process may generate direct metal-to-metal bonds between first electrical bonding structures of a first back-side interconnect structure and second electrical bonding structures of a second front-side interconnect structure. The hybrid bonding process may further generate direct dielectric-to-dielectric bonds between a first dielectric layer of the first back-side interconnect structure and a second dielectric layer of the second front-side interconnect structure. Various other bonding structures may be used to form the die-to-die connection, as described in greater detail below.

Each of the semiconductor dies in a chip stack may include circuit components configured to provide respective functionality (e.g., logic, memory, image processing, power delivery, analog circuits, etc.). Since different functionality may be provided by different semiconductor dies, a set of processing steps that may be used to manufacture a first semiconductor die (e.g., a memory die) and a set of processing steps that may be used to manufacture a second semiconductor die (e.g., a logic die) may be selected independently. The independently manufactured semiconductor dies may then be bonded together in a semiconductor die stack. As such, the performance of the first semiconductor die may be optimized without regard to how the second semiconductor die may be optimized and/or without regard to how the optimization of the first semiconductor die may negatively impact the second semiconductor die or vice versa. For example, a memory die may be optimized with a focus on the density of the memory cells, and a logic die may be optimized with a focus on the device speed, reduction of the process variability, and reliability of semiconductor devices during operation (including, but not limited to, reliability of the device with respect to power supply voltage variation).

Separate manufacturing processes and optimizations of the various semiconductor dies in a semiconductor die stack may allow a chip assembly structure to be produced at lower cost and with improved performance relative to semiconductor devices manufactured using other methods. In some embodiments, a standard layout of electrical bonding structures within front-side interconnect structures and back-side interconnect structures of different semiconductor dies may allow a wide variety of different types of semiconductor dies to be electrically connected to one another to form a chip assembly structure.

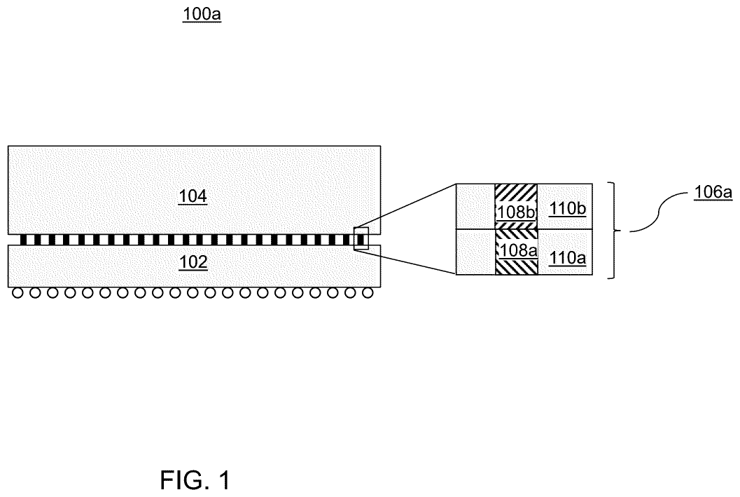

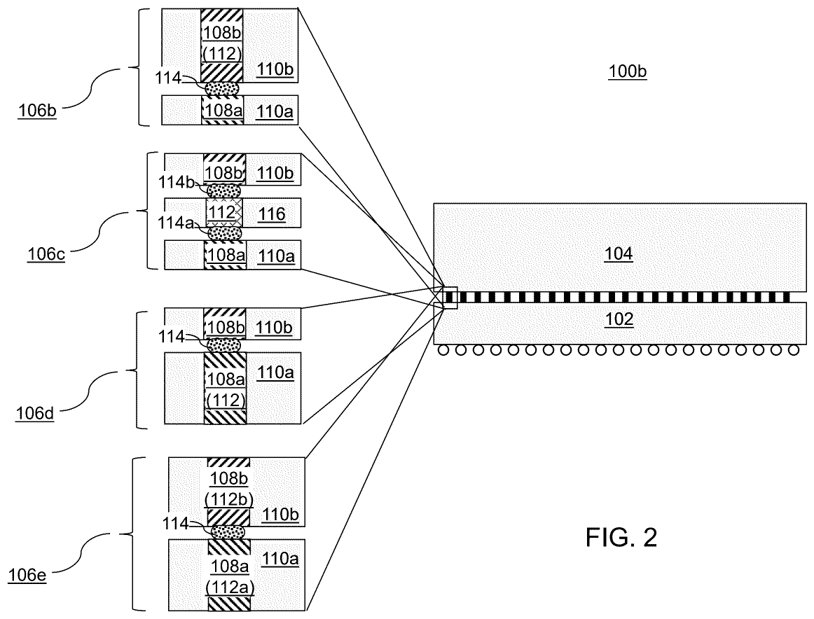

FIG. 1 is a vertical cross-sectional view of a first chip assembly structure 100a including a first semiconductor die 102 and a second semiconductor die 104 illustrating a first bonding configuration 106a, and FIG. 2 is a vertical cross-sectional view of a further chip assembly structure 100b including the first semiconductor die 102 and the second semiconductor die 104 and illustrating further bonding configurations (106b, 106c, 106d, 106e), according to various embodiments. The first semiconductor die 102 may be configured as a control-circuit-containing die, which may include a control circuit and the second semiconductor die 104 may be configured to provide a certain functionality (e.g., memory, logic, etc.). The control circuit of the first semiconductor die 102 may include field effect transistors which are configured to control operation of the second semiconductor die 104. Each of the first semiconductor die 102 and the second semiconductor die 104 may be configured as a double-sided semiconductor die or as a single-sided die.

The example embodiments described below with reference to FIGS. 1 and 2 are merely to illustrate various ways of bonding two structures together. These examples relate to bonding of a first semiconductor die 102 to a second semiconductor die 104. The disclosed embodiments, however, are not limited to bonding between semiconductor dies and may include bonding between any components of a semiconductor package structure such as memory-on-logic bonding, logic-on-logic bonding, bonding between logic and bridge dies, bonding between dies and wafers, wafer-to-wafer bonding, etc. The first semiconductor die 102 may be electrically connected to the second semiconductor die 104 using various types of die-to-die bonding, as indicated by the various bonding configurations (106a, 106b, 106c, 106d, 106e) shown in FIGS. 1 and 2.

In an example embodiment, the first semiconductor die 102 may include first electrical bonding structures 108a and the second semiconductor die 104 may include second electrical bonding structures 108b. In an embodiment in which the second semiconductor die 104 is configured as a memory die, at least a subset of the second electrical bonding structures 108b may be electrically connected to metal interconnect structures in the memory die. As shown in FIG. 1, the first electrical bonding structures 108a may be laterally surrounded by a first bonding-level dielectric layer 110a, which may include a dielectric material that may provide dielectric-to-dielectric bonding (such as silicon oxide) or may include a passivation dielectric material (such as silicon nitride or silicon carbide nitride). Similarly, the second electrical bonding structures 108b may be formed within a second bonding-level dielectric layer 110b.

According to an embodiment, die-to-die bonding between the first semiconductor die 102 and the second semiconductor die 104 may be implemented using metal-to-metal bonding (e.g., see bonding configuration 106a in FIG. 1) or using through-substrate-via-mediated bonding (e.g., see bonding configurations 106b, 106c, 106d, and 106e in FIG. 2). As used herein, “metal-to-metal bonding” refers to a bonding method and a bonded structure in which bonded structures are formed by direct contact between a first metal surface (e.g., first electrical bonding structure 108a in bonding configuration 106a) and a second metal surface (e.g., second electrical bonding structure 108b in bonding configuration 106a) and interdiffusion of metal atoms across a bonding interface between the first metal surface and the second metal surface. An exemplary metal-to-metal bonding is copper-to-copper bonding. In embodiments in which the die-to-die bonding uses metal-to-metal bonding, the first electrical bonding structures 108a (e.g., formed as first copper bonding pads) may be directly bonded to the second electrical bonding structures 108b (e.g., formed as second copper bonding pads).

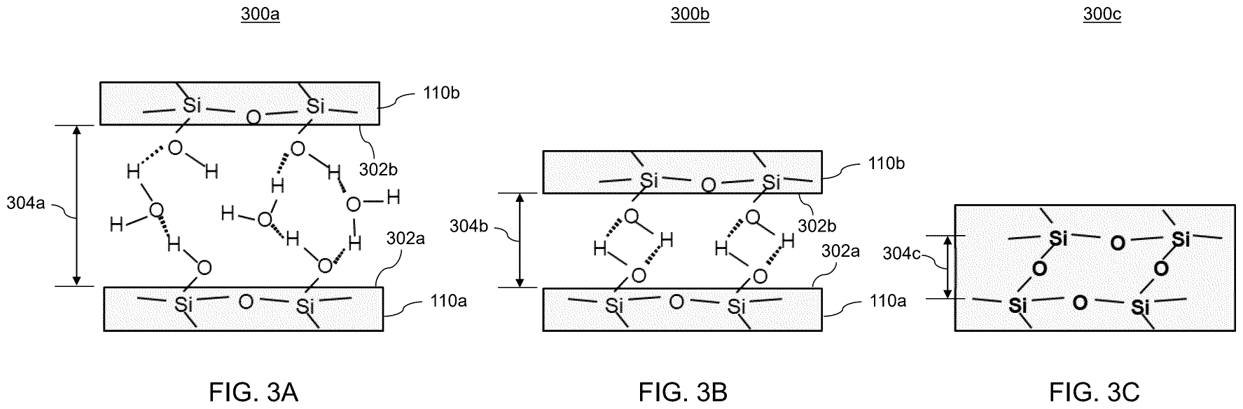

In one embodiment, dielectric bonding between mating pairs of dielectric material layers (110a, 110b) may be used in conjunction with metal-to-metal bonding. This type of bonding (i.e., having metal-to-metal bonding and dielectric-to-dielectric bonding) may be herein referred to as hybrid bonding. In embodiments in which hybrid bonding is used (e.g., see bonding configuration 106a in FIG. 1), the first bonding-level dielectric layer 110a may be bonded to the second bonding-level dielectric layer 110b by dielectric-to-dielectric bonding such as silicon oxide-to-silicon oxide bonding. Dielectric-to-dielectric bonding arises through inter-atomic interactions (e.g., Van der Waals forces, hydrogen bonding, covalent bonding) occurs at the interface between two dielectric materials, as described in greater detail with reference to FIGS. 3A to 3C, below.

As used herein, “through-substrate-via-mediated bonding” refers to a bonding method or a bonding structure in which an array of through-substrate via (TSV) structures (112, 112a, 112b) (e.g., see bonding configurations 106b, 106c, 106d, and 106e in FIG. 2), vertically extending through a surrounding matrix material (110a and/or 110b), is used to provide bonding between the first semiconductor die 102 and the second semiconductor die 104. In a first example embodiment, as shown in bonding configuration 106b of FIG. 2, the array of TSV structures 112 may include the second electrical bonding structures 108b. In other words, the second electrical bonding structures 108b may be formed as the array of TSV structures 112. In this embodiment, an array of solder material portions 114 may be used to provide bonding between the second electrical bonding structures 108b (which are the TSV structures 112) and the first electrical bonding structures 108a. In a second example embodiment, as shown in bonding configuration 106c of FIG. 2, a substrate 116 including an array of TSV structures 112 may be provided. A first array of solder material portions 114a may be used to attach the first electrical bonding structures 108a to the array of TSV structures 112, and a second array of solder material portions 114b may be used to attach the second electrical bonding structures 108b to the array of TSV structures 112.

In a third example embodiment, as shown in bonding configuration 106d in FIG. 2, the array of TSV structures 112 may include the first electrical bonding structures 108a. In other words, the first electrical bonding structures 108a may be formed as the array of TSV structures 112. In this embodiment, an array of solder material portions 114 may be used to provide bonding between the first electrical bonding structures 108a (which are the TSV structures 112) and the second electrical bonding structures 108b. In a fourth example embodiment, as shown in bonding configuration 106e in FIG. 2, each of the first electrical bonding structures 108a and the second electrical bonding structures 108b may be formed as respective arrays of TSV structures (112a, 112b). In this embodiment, an array of solder material portions 114 may be used to provide bonding between the first electrical bonding structures 108a (which are formed as first TSV structures 112a) and the second electrical bonding structures 108b (which are formed as second TSV structures 112b).

In embodiments in which the second semiconductor die 104 is configured as a memory die and the first semiconductor die 102 is configured as a control control-circuit-containing die, electrical nodes of the memory die may be connected to electrical nodes of the control-circuit-containing die through metal-to-metal bonding between mating pairs of electrical bonding structures (108a, 108b), as shown in bonding configuration 106a in FIG. 1, or through an array of TSV structures (112, 112a, 112b), as shown in FIG. 2 in bonding configurations 106b, 106c, 106d, and 106e.

The memory die (e.g., second semiconductor die 104) may include electrical connections for all bit lines and for all word lines within one or more memory arrays within the memory die (e.g., second semiconductor die 104), and the control-circuit-containing die (e.g., first semiconductor die 102) may include the entirety of the control circuit for the memory die. For example, the control-circuit-containing die may include all peripheral circuits including, but not limited to, bit line drivers, word line drivers, sense amplifiers, design-for-testability (DFT) circuits, scan chain circuits, built-in-self-test (BIST) circuits, error correction circuits (ECCs), phase-locked loop (PLL) circuits, electrically-programmable fuse (e-Fuse) circuits, input/output (IO) circuits, voltage generator (power supply) circuits, etc.

Generally, the front side (i.e., the bottom side in the embodiment of FIGS. 1 and 2) or the backside (i.e., the top side in the embodiment of FIGS. 1 and 2) of the first semiconductor die 102 may be used to form the first electrical bonding structures 108a. Likewise, the front side (i.e., the bottom side) or the backside (i.e., the top side) of the second semiconductor die 104 may be used to form the second electrical bonding structures 108b. As such, front-to-front bonding, front-to-back bonding, back-to-front bonding, or back-to-back bonding may be used to bond the second semiconductor die 104 to the first semiconductor die 102. Further, in some embodiments, at least one additional structure may be integrated into the second semiconductor die 104 in addition to the memory die, which may include at least one BEOL structure such as a memory die, logic die, etc.

As described above, dielectric-to-dielectric bonding and/or metal-to-metal bonding (i.e., direct bonding or fusion bonding), is a wafer bonding process in which chemical bonds are formed between two surfaces. In embodiments in which a fusion bonding process is performed, two materials to be bonded must be sufficiently clean, flat, and smooth to avoid unbonded areas (voids, bubbles, etc.). The direct bonding process may include wafer pre-processing, pre-bonding (e.g., at room temperature), and annealing at elevated temperatures. Direct bonding between two silicon surfaces or silicon oxide surfaces, for example, may occur due to intermolecular interactions including Van der Waals forces, hydrogen bonding, and formation of covalent bonds.

In a first operation, the two surfaces to be bonded may be cleaned to remove impurities, particulates, and/or other contaminants from respective surfaces to be bonded. To achieve cleanliness without degrading surface quality, surfaces to be bonded may be subjected to one or more dry or wet cleaning processes. Dry processes may include plasma treatments or ultraviolet (UV)/ozone cleaning, and wet chemical cleaning processes may include treatment of the surfaces to be bonded with one or more wet chemical solutions. In an example embodiment, a wet cleaning process may include application of a first solution (e.g., NH₄ OH (29%)+H₂O₂ (30%)+Deionized H₂O [1:1:5]) followed by application of a second solution (e.g., HCl (37%)+H₂O₂ (30%)+Deionized H₂O [1:1:6]). The first solution may be used to remove organic contaminations and particulates at a temperature of between 70° C. and 80° C. for 5 to 10 min. The second solution may be used for removing metal ions at a temperature of approximately 80° C. for 10 min. Upon completion of a cleaning process, the two surfaces to be bonded may be rinsed with, or stored in, deionized water.

FIG. 3A is a vertical cross-sectional view of an intermediate structure 300a including a first bonding-level dielectric layer 110a and a second bonding-level dielectric layer 110b in a pre-bonding configuration prior to formation of direct dielectric-to-dielectric bonds. The pre-bonding configuration of FIG. 3A may be formed by placing the first bonding-level dielectric layer 110a and the second bonding-level dielectric layer 110b (each of which having been cleaned) within close proximity to one another. As shown in FIG. 3A, for example, a first surface 302a of the first bonding-level dielectric layer 110a may be positioned to be facing a second surface 302b of the second bonding-level dielectric layer 110b. In some embodiments, the first surface 302a may be parallel to the second surface 302b. In some embodiments, the first bonding-level dielectric layer 110a and the second bonding-level dielectric layer 110b may be surface oxide layers of respective silicon wafers. After the cleaning process has been performed, each of first bonding-level dielectric layer 110a and the second bonding-level dielectric layer 110b may have chemisorbed water molecules (H₂O) attached to the silicon oxide surfaces (302a, 302b) of the respective dielectric layers (110a, 110b) as shown, for example, in FIG. 3A.

The pre-bonding configuration of FIG. 3A may correspond to a first separation distance 304a between the first surface 302a and the second surface 302b. For example, the first separation distance 304a may be between 1.1 nm and 1.2 nm. At such a separation, the chemisorbed water molecules may begin to interact and to form bonds. The bonds may include hydrogen bonds between water molecules and Van der Waals interactions. In addition to such relatively weak interactions, strong covalent bonds may begin to form. In this regard, silanol groups (i.e., Si—OH groups) may begin to polymerize (i.e., form covalent bonds) at room temperature. The polymerization process is governed by the chemical equation: Si—OH+OH—Si→Si—O—Si+H₂O, which generates direct Si—O—Si bonds (i.e., siloxane compounds) and releases water molecules (H₂O).

After allowing the pre-bonding process to proceed in air, in a special gaseous atmosphere or in vacuum, the first bonding-level dielectric layer 110a and the second bonding-level dielectric layer 110b may then be subjected to an annealing process at elevated temperatures to cause further polymerization of the silanol groups. During the annealing process, additional Si—O—Si bonds may be formed and additional water molecules may be liberated. The water molecules generated during the polymerization reaction may migrate or diffuse along the interface between the first surface 302a and the second surface 302b during the annealing process.

FIG. 3B is a vertical cross-sectional view of a further intermediate structure 300b including the first bonding-level dielectric layer 110a and the second bonding-level dielectric layer 110b of FIG. 3A in a bonding configuration during formation of direct dielectric-to-dielectric (i.e., covalent) bonds. During the annealing process, the strength of the bonds between the first surface 302a and the second surface 302b may increase as compared to the configuration shown in FIG. 3A and the separation between the first surface 302a and the second surface 302b may decrease as compared to the configuration shown in FIG. 3A. For example, as shown in FIG. 3B, during the annealing process the separation distance may decrease to a second separation distance 304b having a value between 0.55 nm and 0.65 nm as additional Si—O—Si bonds are formed. Under further annealing, the separation between the first surface 302a and the second surface 302b may continue to decrease with increasing bonding strength until a bonded structure 300c (e.g., see FIG. 3C) is formed. In this regard, the bonded structure may have a third separation distance 304c that may be between 0.3 nm and 0.5 nm.

FIG. 3C is a vertical cross-sectional view of a bonded structure 300c after formation of direct dielectric-to-dielectric bonds between the first bonding-level dielectric layer 110a and the second bonding-level dielectric layer 110b. The bonded structure 300c of FIG. 3C may be formed at the conclusion of the annealing process. The annealing process provides a certain amount of thermal energy to chemically reacting molecular species. This thermal energy may cause additional silanol groups to react with one another to thereby generate highly stable chemical bonds between Si and O atoms across the interface between the first surface 302a and the second surface 302b. The number of covalent bonds formed may depend on the amount of energy delivered to the bonding molecules, which in turn, depends on the annealing temperature. Thus, within a certain temperature range, interfacial bonding strength may increase with increasing annealing temperatures. For example, between room temperature and 110° C. (i.e., during the pre-bonding phase) the interfacial bonding energy (i.e., that characterizes interfacial bonding strength) may be relatively low (i.e., with a low fraction of covalent bonds). At such temperatures the polymerization of silanol may begin but is limited. During this phase, water molecules diffuse at the bond interface causing various rearrangements of silanol molecules, causing more hydrogen-bonds (i.e., weak bonds relative to Si—O—Si covalent bonds) to form between chemisorbed water molecules.

At temperatures from 110° C. to 150° C. silanol groups polymerize thereby generating siloxane and water. At a given annealing temperature, which is maintained for a sufficient time, a thermodynamic equilibrium may be established in which a first fraction of un-reacted silanol groups may be in equilibrium with a second fraction of siloxane (i.e., chains of Si—O—Si bonded groups). Thus, for a given temperature range, increasing annealing temperature may lead to an increased second fraction of siloxane and a corresponding increased interfacial bond strength. In this regard, an interfacial bond strength may increase with temperature from 150° C. to 800° C. until most or all of the OH-groups are polymerized and the composite strength reaches a constant value. Above 800° C. native oxide may become viscous and may flow at the interface to thereby increase an area of contacted surfaces. At such temperatures, diffusion of trapped hydrogen molecules along the interface may be enhanced and interface voids may be reduced in size or may disappear. The annealing process may conclude with the cooling of the bonded structure 300c down to room temperature.

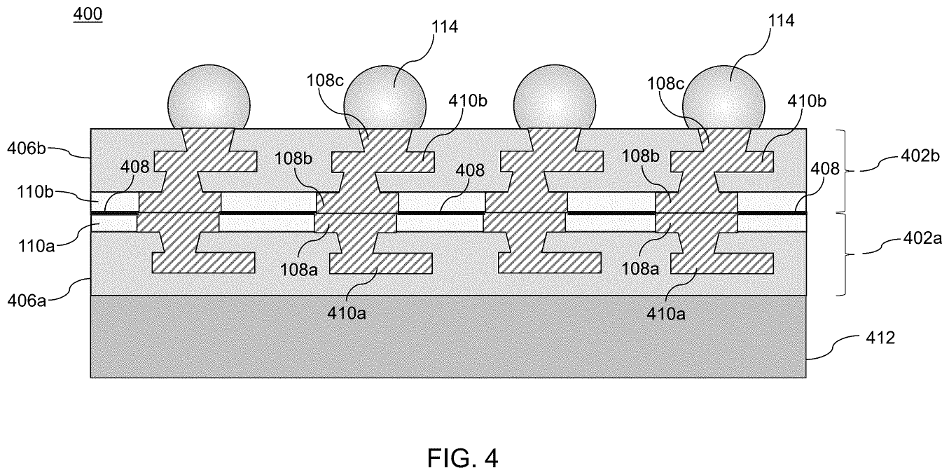

FIG. 4 is a vertical cross-sectional view of a semiconductor structure 400 having improved dielectric-to-dielectric bonding structures, according to various embodiments. The semiconductor structure 400 may include a first component 402a and a second component 402b. The first component 402a may include first electrical bonding structures 108a formed within a first dielectric layer 110a and the second component 402b may include second electrical bonding structures 108b formed with a second dielectric layer 110b. As described above, the first dielectric layer 110a (referred to as a first bonding-level dielectric layer 110a, above) may be formed of silicon dioxide, silicon nitride, silicon carbide nitride, etc., and may be formed over a first semiconductor substrate 406a. The first semiconductor substrate 406a may be a silicon substrate, a silicon-on-insulator (SOI) substrate, etc. Similarly, the second dielectric layer 110b (referred to as a second bonding-level dielectric layer 110b, above) may be formed of silicon dioxide, silicon nitride, silicon carbide nitride, etc., and may be formed over a second semiconductor substrate 406b. The second semiconductor substrate 406b may also be a silicon substrate, a silicon-on-insulator (SOI) substrate, etc. In this example embodiment, the first semiconductor substrate 406a may be mounted to a carrier substrate 412.

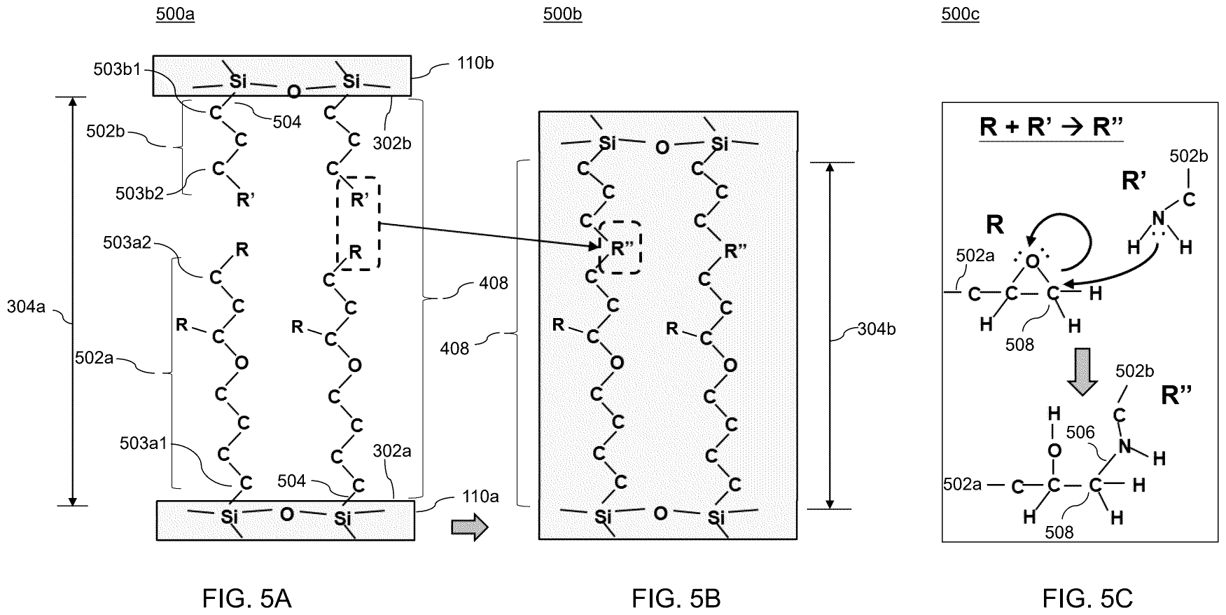

The semiconductor structure 400 may further include an organic base layer 408 formed between the first dielectric layer 110a and the second dielectric layer 110b such that the first dielectric layer 110a is bonded to the second dielectric layer 110b with bonds formed between the first dielectric layer 110a, the organic base layer 408, and the second dielectric layer 110b. As described in greater detail with reference to FIGS. 5A and 5B, below, the organic base layer 408 may include carbon chain structures (502a, 502b) and may have a thickness that is between 0.5 nm and 30 nm.

The organic base layer 408 may be used in a modified fusion bonding (i.e., dielectric-to-dielectric) bonding process. In this regard, the organic base layer 408 may be selectively placed on dielectric bonding surfaces (see 302a, 302b in FIGS. 3A and 3B) of bonded dielectric layers (110a, 110b) and may lead to dielectric-to-dielectric bonds having increased strength relative to dielectric-to-dielectric bonds generated without the organic base layer 408 (i.e., using a process similar to that described above with reference to FIGS. 3A to 3C). The use of the organic base layer 408 may allow dielectric-to-dielectric bonds to be formed at an annealing temperature that may be considerably reduced (i.e., between 150° C. and 350° C.) in contrast to annealing at temperatures (i.e., up to 800° C.) in the process described above with reference to FIGS. 3A to 3C. The organic base layer 408 may also act to reduce internal stresses between bonded dielectric layers (110a, 110b) and may also allow surfaces to be bonded that have a greater roughness than may be tolerated using the processes described above with reference to FIGS. 3A to 3C. The semiconductor structure 400 of FIG. 4 may further include metal-to-metal bonds formed between the first electrical bonding structures 108a and the second electrical bonding structures 108b, as described in greater detail with reference to FIGS. 1 and 2, above.

According to various embodiments, the first component 402a may be a semiconductor die (102, 104) as described above with reference to FIGS. 1 and 2. For example, the first component 402a may include electrical circuits (not shown) formed in an FEOL or BEOL process. The first component 402a may further include first electrical interconnect structures 410a electrically coupled to the first electrical bonding structures 108a. The first electrical interconnect structure 410a may be formed within first semiconductor substrate 406a. Similarly, the second electrical interconnect structure 410b may be formed within second semiconductor substrate 406b. As described above, however, the disclosed embodiments need not limited to bonding between semiconductor dies (102, 104) and may include bonding between any components of a semiconductor package structure (100a, 100b) such as memory-on-logic bonding, logic-on-logic bonding, bonding between logic and bridge dies, bonding between dies and wafers, wafer-to-wafer bonding, etc.

For example, the second component 402b may be one of a second semiconductor die (102, 104), an interposer, or a package substrate. The second component 402b may include second electrical interconnect structures 410b electrically coupled to the second electrical bonding structures 108b. As shown in FIG. 4, for example, the second component 402b may further include third electrical bonding structures 108c formed on a side of the second component 402b opposite to the second electrical bonding structures 108b. The third bonding structures may be electrically connected to the second electrical bonding structures 108b through the second electrical interconnect structures 410b. Solder material portions 114 may also be provided on surfaces of the third electrical bonding structures 108c such that that second component 402b may be electrically connected to a third component (not shown) to thereby form a semiconductor package structure (100a, 100b) having a stacked structure as described with reference to FIG. 2, above. Alternatively, the second component 402b of FIG. 4 may be configured as an interposer or a package substrate such that the semiconductor structure 400 of FIG. 4 may be electrically connected to a printed circuit board (not shown) in a subsequent package assembly operation.

FIG. 5A is a vertical cross-sectional view of an intermediate structure 500a including a first dielectric layer 110a and a second dielectric layer 110b in a pre-bonding configuration prior to formation of direct dielectric-to-dielectric bonds using an organic base layer 408 (e.g., see FIG. 4), according to various embodiments. As shown, the organic base layer 408 may include a plurality of carbon chain structures (502a, 502b). In this regard, a first carbon chain structure 502a may be formed on a first surface 302a of a first dielectric layer 110a and a second carbon chain structure 502b may be formed on a second surface 302b of a second dielectric layer 110b. As shown, the first dielectric layer 110a and the second dielectric layer 110b may be placed within proximity to one another such that the first surface 302a is facing the second surface 302b. In some embodiments, the first surface 302a may be parallel to the second surface 302b. Each of the carbon chain structures (502a, 502b) may include carbon-silicon bonds 504 at a first surface 302a of the first dielectric layer 110a and at a second surface 302b of the second dielectric layer 110b. The intermediate structure 500a may correspond to a pre-bonding configuration in which the first surface 302a and the second surface 302b may be separated by a first separation distance 304a that may be between that may be between 0.5 nm and 30 nm.

According to various embodiments, the carbon chain structures (502a, 502b) may further include one or more organic functional groups (R, R′) bound to one or more carbon atoms in the carbon chain structures (502a, 502b). In this regard, each of the carbon chain structures (502a, 502b) may include a respective proximal end (503a1, 503b1) bonded to the respective dielectric layers (110a, 110b) with carbon-silicon bonds 504 and a respective distal end (503a2, 503b2) bonded to a respective organic functional group (R, R′), as shown in FIG. 5A. The organic functional groups (R, R′) may include one or more of amines, epoxides, carboxyl groups, isocyanate groups, hydroxyl groups, and compounds formed from reactions between two or more or more of amines, epoxides, carboxyl groups, isocyanate groups, hydroxyl groups. The presence of the organic functional groups (R, R′) may facilitate bonding between the carbon chain structures (502a, 502b), as described in further detail with reference to FIGS. 5B and 5C.

FIG. 5B is a vertical cross-sectional view of a bonded structure 500b after formation of direct dielectric-to-dielectric bonds between the first dielectric layer 110a and the second dielectric layer 110b of FIG. 5A, and FIG. 5C illustrates an example chemical reaction that may occur between organic functional groups (R, R′) attached to carbon chain structures (502a, 502b), according to various embodiments. As shown in FIG. 5C, an epoxide group may be an example of a first organic functional group R that may be attached to the first carbon chain structure 502a and an amine group may be an example of a second organic functional group R′ that may be attached to the second carbon chain structure 502b. As shown in FIG. 5C the first organic functional group R may chemically react with the second organic functional group R′ to form a bonded molecular structure R″.

As shown in FIG. 5C, the bonded molecular structure R″ may include a covalent bond 506 that bonds the first carbon chain structure 502a to the second carbon chain structure 502b. In this example, the covalent bond 506 may be formed between the nitrogen atom of the second organic functional group R′ (i.e., the amine group) and one of the carbon atoms 508 of the first organic functional group R (i.e., the epoxide group). According to some embodiments, the bonded structure 500b may be formed by subjecting the intermediate structure 500a to an elevated temperature that is between 150° C. and 350° C. and a pressure that is between 0.1 N/cm² and 500 N/cm². In addition to reactions between organic functional groups (R, R′) formed at the ends of the carbon chain structures (502a, 502b), additional reactions may occur between neighboring carbon chain structures (502a, 502b) in side-chain reactions (e.g., reactions between organic functional groups attached to sides of the carbon chain structures (502a, 502b)).

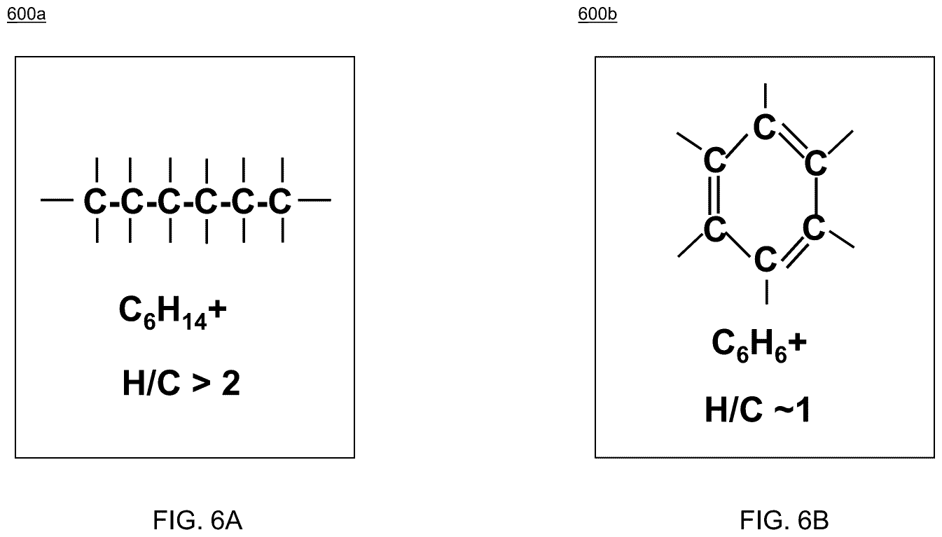

FIG. 6A illustrates an example carbon chain structure 600a having a hydrogen/carbon ratio that is greater than 2, and FIG. 6B illustrates a comparative example cyclic carbon molecule 600b having a hydrogen/carbon ratio that is approximately equal to 1, according various embodiments. Measurements made using a technique such as time-of-flight secondary ion mass spectroscopy (ToF-SIMS) may be used to determine the hydrogen/carbon ratio of a molecular structure as well as the carbon number (i.e., number of atoms in the structure). As shown in FIG. 6A, a hydrogen/carbon ratio that is greater than 2 may indicate a carbon chain structure (i.e., having single carbon-carbon bonds) while a hydrogen/carbon ratio closer to 1 may indicate a carbon structure that does not have a chain structure. For example, the cyclic molecule C₆H₆ (i.e., benzene) has single, as well as double, carbon bonds and, as such, is not a carbon chain structure. According to various embodiments, the carbon chain structures (502a, 502b) may be characterized by a carbon number (i.e., number of atoms in the chain) between 10 and 1000. The resulting organic base layer 408 may have a corresponding thickness (i.e., a value of the second separation distance 304b in FIG. 5B) that may be between 0.5 nm and 30 nm. These values for the carbon number and thickness of the organic base layer 408 may represent optimal values regarding bonding characteristics of the organic base layer 408. In this regard, carbon chains that are too long may become twisted and therefore may have reduced bonding efficiency due to steric hindrance. Similarly, in embodiments in which the chains are too short there may be fewer functional groups available to form chemical bonds.

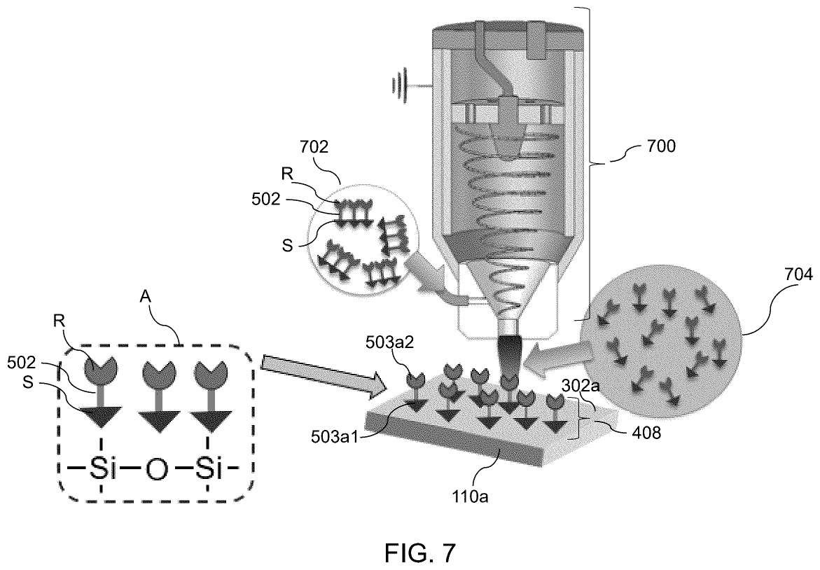

FIG. 7 is a three-dimensional perspective view of a plasma jet apparatus 700 that may be used to deposit an organic base layer 408 on a first surface 302a of a first dielectric layer 110a, according to various embodiments. In this regard, a solution 702 may be formed that includes carbon chain structures 502 dissolved in an organic solvent. In a first chemical synthesis process, the carbon chain structures 502 may be formed as a precursor compound in which the carbon chain structures 502 may each have a first end bonded to a silanol group S (i.e., a molecule including a Si—OH group) and a second end bonded to an organic functional group R. In various embodiments, the organic functional group R may be one of an amine, and epoxide, a carboxyl group, an isocyanate group, a hydroxyl group, or a compound formed from a reaction between two or more of an amine, and epoxide, a carboxyl group, an isocyanate group, a hydroxyl group.

The solution 702 may then be introduced into the plasma jet apparatus 700 which may then form a plasma 704 containing fragments of the precursor compound. The plasma 704 may then be directed at the first surface 302a of the first dielectric layer 110a. As illustrated in the inset A, the carbon chain structures 502 may bond to the surface 302a such that the silane groups S form bonds with an inorganic backbone (i.e., Si—O—Si structure) at the first surface 302a of the first dielectric layer 110a. As such, the carbon chain structures 502 may each have a proximal end 503al bonded to the first dielectric layer 110a with first carbon-silicon bonds 504 and a distal end 503a2 attached an organic functional group R, as described in greater detail with reference to FIGS. 5A and 5B, above. The above-described deposition process using a plasma jet apparatus 700 is merely one example of a method of depositing the organic base layer 408 on the first surface 302a of the first dielectric layer 110a. Other techniques such as spin coating or spray deposition may also be used in other embodiments.

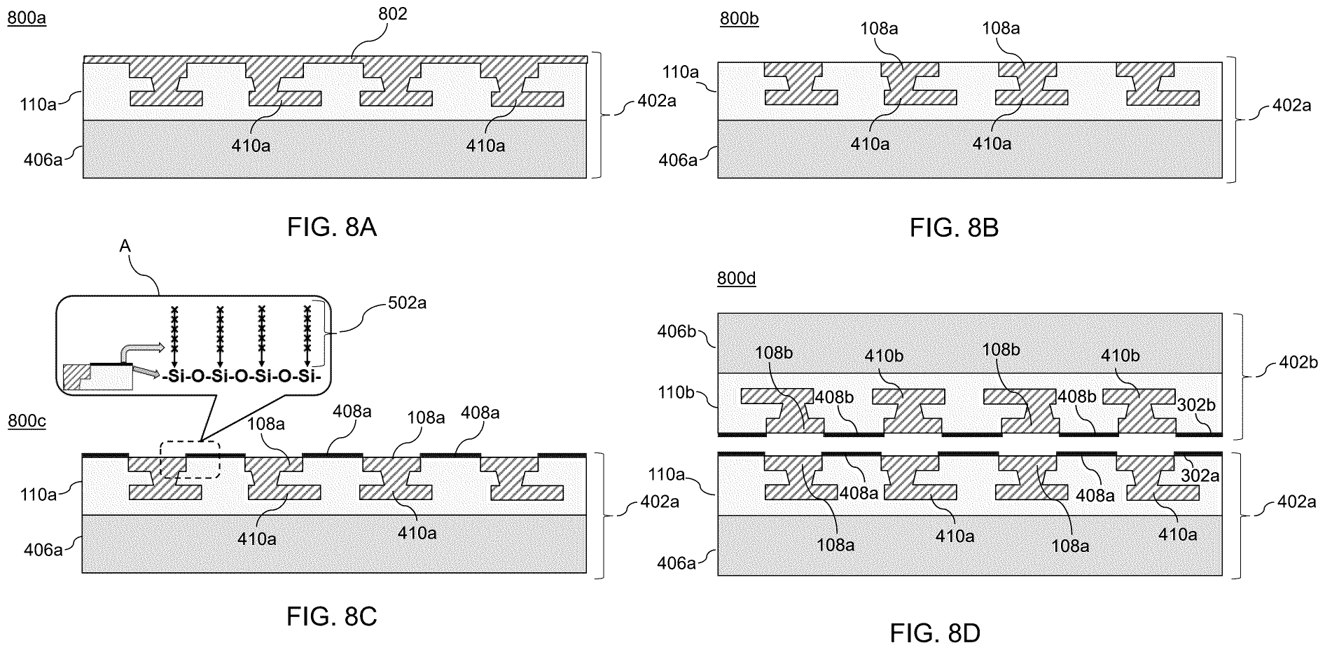

FIGS. 8A to 8D are vertical cross-sectional views of respective intermediate structures (800a to 800d) that may be used in the formation of a semiconductor structure, according to various embodiments. As shown in FIG. 8A, the intermediate structure 800a may include a first component 402a having first electrical interconnect structures 410a formed in a first bonding-level dielectric layer 110a. The first bonding-level dielectric layer 110a may be formed over a first semiconductor substrate 406a. The first semiconductor substrate 406a may be a silicon substrate, a silicon-on-insulator (SOI) substrate, etc. The intermediate structure 800a may further have an electrically conducting material 802 formed over a top surface of the first bonding-level dielectric layer 110a.

The electrically conducting material 802 may be formed over openings (not shown) formed in the first bonding-level dielectric layer 110a. In this regard, the openings may be etched in the first bonding-level dielectric layer 110a such that top surfaces of the first electrical interconnect structures 410a may be exposed. The electrically conducting material 802 may be deposited over the openings in the first bonding-level dielectric layer 110a using various techniques, such as by electroplating. In this way, the electrically conducting material 802 may make electrical contact with the first electrical interconnect structures 410a. A planarization process (e.g., chemical mechanical planarization (CMP)) may then be performed to remove excess portions of the electrically conducting material 802 formed over a top surface of the intermediate structure 800a to thereby form the intermediate structure 800b of FIG. 8B. As shown in FIG. 8B, the resulting intermediate structure 800b may include first electrical bonding structures 108a formed withing the first bonding-level dielectric layer 110a.

In a further operation, a first organic base layer 408a may be formed over the first bonding-level dielectric layer 110a, as shown in the intermediate structure 800c of FIG. 8C. As shown in the inset A of FIG. 8C, the first organic base layer 408a may include a plurality of first carbon chain structures 502a attached to an inorganic backbone (i.e., Si—O—Si structures) formed on the first bonding-level dielectric layer 110a. As described above with reference to 7, the first organic base layer 408a may be deposited over the first bonding-level dielectric layer 110a using a plasma jet apparatus 700 that may be used to perform a plasma jet deposition process. Alternatively, the first organic base layer 408a may be deposited using other techniques such as spray deposition or spin coating. Further, the first organic base layer 408a may be selectively deposited over surfaces of the first bonding-level dielectric layer 110a. For example, a patterned mask material (not shown), such as a photoresist, may be used to mask the first electrical bonding structures 108a so that the first organic base layer 408a is not formed over the first electrical bonding structures 108a.

The intermediate structure 800d of FIG. 8D may be formed from the intermediate structure 800c by placing a second component 402b within proximity to the first component 402a such that a first surface 302a of the first bonding-level dielectric layer 110a is facing, and is parallel to, a second surface 302b of a second bonding-level dielectric layer 110b of the second component 402b. As shown, the second component 402b may include second electrical bonding structures 108b formed in a second bonding-level dielectric layer 110b. The second electrical bonding structures 108b may be electrically connected to second electrical interconnect structures 410b and the second bonding-level dielectric layer 110b may be formed over a second semiconductor substrate 406b. The second component 402b may further include a second organic base layer 408b formed over surfaces of the second bonding-level dielectric layer 110b. Further, the second organic base layer 408b may be selectively deposited over surfaces of the second bonding-level dielectric layer 110b. In this regard, as described above, a patterned mask material (not shown), such as a photoresist, may be used to mask the second electrical bonding structures 108b so that the second organic base layer 408b is not formed over the second electrical bonding structures 108b.

A bonded semiconductor structure (see FIGS. 4 and 5B, 400, 500b) may then be formed by performing a bonding process to bond carbon chain structures (502a, 502b) of the organic base layer 408, as described in greater detail with reference to FIGS. 5A to 5C, above. In this regard, first organic functional groups R attached to first carbon chain structures 502a may chemically react with second organic functional groups R′ attached to second carbon chain structures 502b. As described above with reference to FIG. 5C, the reaction of a first organic functional group R with a second organic functional group R″ may result in the formation of a new molecular structure R″ that binds the first carbon chain structure 502a to the second carbon chain structure 502b. In this regard, one or more covalent bonds 506 may be formed between the first carbon chain structure 502a and the second carbon chain structure 502b, as shown in FIG. 5C and described in greater detail, above.

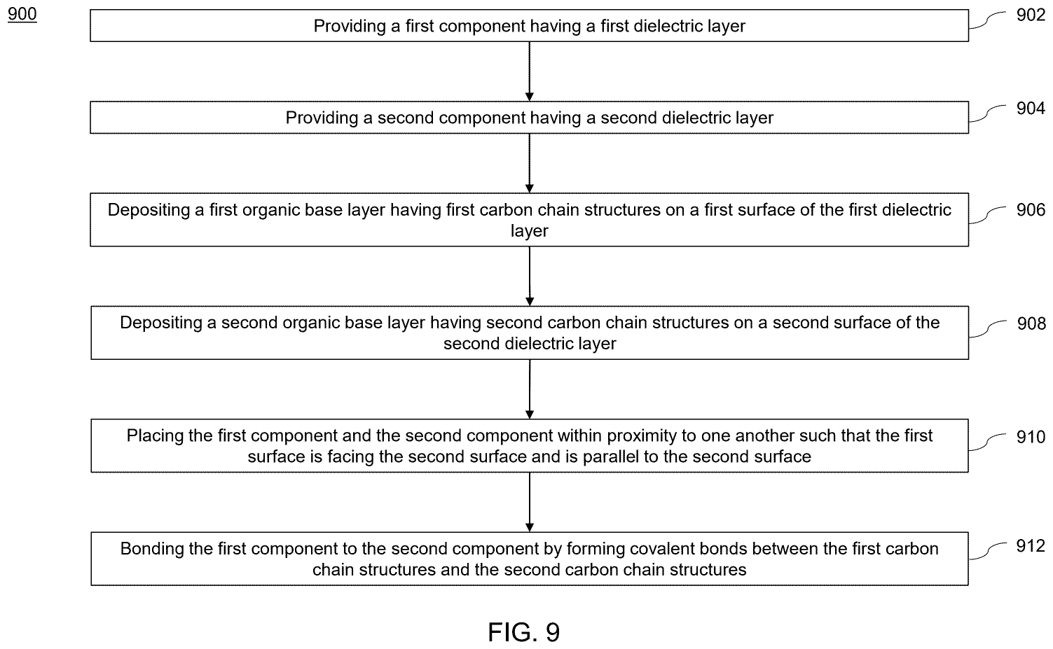

FIG. 9 is a flowchart illustrating operations of a method 900 of forming a semiconductor structure 400, according to various embodiments. In operation 902, the method 900 may include providing a first component 402a having a first dielectric layer 110a, and in operation 904, the method 900 may include providing a second component 402b having a second dielectric layer 110b. In operation 906, the method 900 may include depositing a first organic base layer 408a having first carbon chain structures 502a on a first surface 302a of the first dielectric layer 110a. Similarly, in operation 908, the method 900 may include depositing a second organic base layer 408b having second carbon chain structures 502b on a second surface 302b of the second dielectric layer 110b. In operation 910, the method 900 may include placing the first component 402a and the second component 402b within proximity to one another such that the first surface 302a is facing the second surface 302b. In some embodiments, the first surface 302a may be parallel to the second surface 302b. In operation 912, the method 900 may include bonding the first component 402a to the second component 402b by forming covalent bonds 506 between the first carbon chain structures 502a and the second carbon chain structures 502b to thereby form the semiconductor structure 400 (e.g., see FIGS. 4 to 5C).

In forming covalent bonds 506 according to operation 912, the method 900 may further include forcing the first surface 302a and the second surface 302b toward one another with a pressure that is between 0.1 N/cm² and 500 N/cm² and by subjecting the semiconductor structure 400 to an elevated temperature that is between 150° C. and 350° C. In depositing the first organic base layer 408a on the first surface 302a according to operation 906, and depositing the second organic base layer 408b on the second surface 302b according to operation 908, the method 900 may further include forming a solution 702 including carbon chain structures (502a, 502b) in an organic solvent. The method 900 may further include depositing the solution 702 on the first surface 302a and the second surface 302b to thereby form the first organic base layer 408a and the second organic base layer 408b, respectively. In some embodiments, depositing the solution 702, according to operations 906 and 908 of the method 900, may further include performing a plasma jet process (e.g., see FIG. 7 and related description), a spin coating process, or a spray coating process, to thereby deposit the solution 702 on the first surface 302a and the second surface 302b.

According to the method 900, forming the solution 702 further may include forming a precursor compound including the carbon chain structures (502a, 502b) each having a first end bonded to a silanol group S and a second end bonded to an organic functional group (R, R′) and dissolving the precursor compound in the organic solvent. According to the method 900, the organic functional group (R, R′) may include one of an amine, and epoxide, a carboxyl group, an isocyanate group, a hydroxyl group, or a compound formed from a reaction between two or more of an amine, and epoxide, a carboxyl group, an isocyanate group, a hydroxyl group. According to the method 900, forming the precursor compound may further include forming carbon chain structures (502a, 502b) having a carbon number that is between 10 and 1000 and having a hydrogen to carbon ratio H/C that is greater than 2.

Referring to all drawings and according to various embodiments of the present disclosure, a semiconductor structure 400 is provided. The semiconductor structure 400 may include a first component 402a having first electrical bonding structures 108a formed within a first dielectric layer 110a and a second component 402b having second electrical bonding structures 108b formed with a second dielectric layer 110b. The semiconductor structure 400 may further include an organic base layer 408, including carbon chain structures (502a, 502b), formed between the first dielectric layer 110a and the second dielectric layer 110b. In this regard, the first dielectric layer 110a may be bonded to the second dielectric layer 110b with bonds formed between the first dielectric layer 110a, the organic base layer 408, and the second dielectric layer 110b. The semiconductor structure 400 may further include metal-to-metal bonds formed between the first electrical bonding structures 108a and the second electrical bonding structures 108b.

According to various embodiments, the carbon chain structures (502a, 502b) may be characterized by a carbon number that is between 10 and 1000 and a hydrogen to carbon ratio H/C that is greater than 2. Further, the organic base layer 408 may have a thickness that is between 0.5 nm and 30 nm. The carbon chain structures (502a, 502b) may further include carbon-silicon bonds 504 at a first surface 302a of the first dielectric layer 110a and at a second surface 302b of the second dielectric layer 110b. The carbon chain structures (502a, 502b) may further include one or more organic functional groups (R, R′) bound to one or more carbon atoms in the carbon chain structures (502a, 502b). In various embodiments, the organic functional groups (R, R′) may include one or more of amines, epoxides, carboxyl groups, isocyanate groups, hydroxyl groups, and compounds formed from reactions between two or more or more of amines, epoxides, carboxyl groups, isocyanate groups, hydroxyl groups.

According to some embodiments, the first component 402a may be a semiconductor die (102, 104) including first electrical interconnect structures 410a electrically coupled to the first electrical bonding structures 108a. The second component 402b may be one of a second semiconductor die (102, 104), an interposer, or a package substrate. Further, the second component 402b may include second electrical interconnect structures 410b electrically coupled to the second electrical bonding structures 108b.

According to other embodiments, a further semiconductor structure 400 is provided. The semiconductor structure 400 may include a first component 402a having a first dielectric layer 110a and a first organic base layer 408a including first carbon chain structures 502a formed on a first surface 302a of the first dielectric layer 110a. The first carbon chain structures 502a may each include a first proximal end 503a1 bonded to the first dielectric layer 110a with first carbon-silicon bonds 504 and a first distal end 503a2 including a first organic functional group R. The first carbon chain structures 502a may be characterized by a carbon number that is between 10 and 1000 and a hydrogen to carbon ratio H/C that is greater than 2. According to various embodiments, the first organic functional group R may include one of an amine, an epoxide, a carboxyl group, an isocyanate group, a hydroxyl group, or a compound formed from a reaction between two or more of an amine, an epoxide, a carboxyl group, an isocyanate group, a hydroxyl group.

According to various embodiments, the semiconductor structure 400 may further a second component 402b including a second dielectric layer 110b and a second organic base layer 408b including second carbon chain structures 502b formed on a second surface 302b of the second dielectric layer 110b. The second carbon chain structures 502b may each include a second proximal end 503b1 bonded to the second dielectric layer 110b with second carbon-silicon bonds 504 and a second distal end 503b2 including a second organic functional group R′. In various embodiments, first component 402a and the second component 402b may be bonded to one another through covalent bonds 506 formed between the first organic functional group R and the second organic functional group R′. A combined thickness of the first organic base layer and the second organic base layer may be between 0.5 nm and 30 nm.

Disclosed embodiments may be advantageous by providing an organic base layer 408 that may be used in a modified dielectric-to-dielectric bonding process. The organic base layer 408 may generate dielectric-to-dielectric bonds having an increased strength relative to dielectric-to-dielectric bonds generated without the use of the organic base layer 408. The organic base layer 408 may also allow dielectric-to-dielectric bonds to be formed at an annealing temperature (e.g., between 150° C. and 350° C.) that may be considerably reduced relative to annealing temperatures (e.g., up to 800° C.) of processes that do not include the organic base layer 408. The organic base layer 408 may act to reduce internal stresses between bonded dielectric layers (110a, 110b) and may also allow dielectric bonding surfaces (302a, 302b) to be bonded that have a greater degree of roughness than may be tolerated using alternative dielectric-to-dielectric bonding processes.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A semiconductor structure, comprising:
a first component comprising first electrical bonding structures formed within a first dielectric layer;
a second component comprising second electrical bonding structures formed with a second dielectric layer; and
an organic base layer, comprising carbon chain structures, formed between the first dielectric layer and the second dielectric layer such that the first dielectric layer is bonded to the second dielectric layer with bonds formed between the first dielectric layer, the organic base layer, and the second dielectric layer.

2. The semiconductor structure of claim 1, further comprising metal-to-metal bonds formed between the first electrical bonding structures and the second electrical bonding structures.

3. The semiconductor structure of claim 1, wherein the carbon chain structures are characterized by a carbon number that is between 10 and 1000.

4. The semiconductor structure of claim 1, wherein the carbon chain structures are characterized by a hydrogen to carbon ratio H/C that is greater than 2.

5. The semiconductor structure of claim 1, wherein the organic base layer has a thickness that is between 0.5 nm and 30 nm.

6. The semiconductor structure of claim 1, wherein the carbon chain structures comprise carbon-silicon bonds at a first surface of the first dielectric layer and at a second surface of the second dielectric layer.

7. The semiconductor structure of claim 1, wherein the carbon chain structures further comprise one or more organic functional groups bound to one or more carbon atoms in the carbon chain structures.

8. The semiconductor structure of claim 7, wherein the one or more organic functional groups comprise one or more of amines, epoxides, carboxyl groups, isocyanate groups, hydroxyl groups, and compounds formed from reactions between two or more or more of amines, epoxides, carboxyl groups, isocyanate groups, hydroxyl groups.

9. The semiconductor structure of claim 1, wherein the first component is a semiconductor die comprising first electrical interconnect structures electrically coupled to the first electrical bonding structures,
wherein the second component is one of a second semiconductor die, an interposer, or a package substrate, and
wherein the second component comprises second electrical interconnect structures electrically coupled to the second electrical bonding structures.

10. A semiconductor structure, comprising:
a first component comprising a first dielectric layer; and
a first organic base layer, comprising first carbon chain structures, formed on a first surface of the first dielectric layer,
wherein the first carbon chain structures each comprise:
a first proximal end bonded to the first dielectric layer with first carbon-silicon bonds; and
a first distal end comprising a first organic functional group.

11. The semiconductor structure of claim 10, wherein the first carbon chain structures comprise a carbon number that is between 10 and 1000.

12. The semiconductor structure of claim 10, wherein the first carbon chain structures comprise a hydrogen to carbon ratio H/C that is greater than 2.

13. The semiconductor structure of claim 10, wherein the first organic functional group comprises one of an amine, an epoxide, a carboxyl group, an isocyanate group, a hydroxyl group, or a compound formed from a reaction between two or more of an amine, an epoxide, a carboxyl group, an isocyanate group, a hydroxyl group.

14. The semiconductor structure of claim 13, further comprising:
a second component comprising a second dielectric layer; and
a second organic base layer, comprising second carbon chain structures, formed on a second surface of the second dielectric layer,
wherein the second carbon chain structures each comprise:
a second proximal end bonded to the second dielectric layer with second carbon-silicon bonds; and
a second distal end comprising a second organic functional group, and
wherein the first component and the second component are bonded to one another through covalent bonds formed between the first organic functional group and the second organic functional group.

15. The semiconductor structure of claim 14, wherein a combined thickness of the first organic base layer and the second organic base layer is between 0.5 nm and 30 nm.

16. A method of forming a semiconductor structure, comprising:
providing a first component comprising a first dielectric layer;
providing a second component comprising a second dielectric layer;
depositing a first organic base layer, comprising first carbon chain structures, on a first surface of the first dielectric layer;
depositing a second organic base layer, comprising second carbon chain structures, on a second surface of the second dielectric layer;
placing the first component and the second component within proximity to one another such that the first surface is facing the second surface; and
bonding the first component to the second component by forming covalent bonds between the first carbon chain structures and the second carbon chain structures to thereby form the semiconductor structure.

17. The method of claim 16, wherein bonding the first component to the second component further comprises:
forcing the first surface and the second surface toward one another with a pressure that is between 0.1 N/cm² and 500 N/cm²; and
subjecting the semiconductor structure to an elevated temperature that is between 150° C. and 350° C.

18. The method of claim 16, wherein depositing the first organic base layer and the second organic base layer on the first surface and the second surface, respectively, further comprises:
forming a solution comprising carbon chain structures in an organic solvent; and
depositing the solution on the first surface and the second surface to thereby form the first organic base layer and the second organic base layer, respectively,
wherein depositing the solution further comprises performing a plasma jet process, a spin coating process, or a spray coating process, to thereby deposit the solution on the first surface and the second surface.

19. The method of claim 18, wherein forming the solution further comprises:
forming a precursor compound comprising the carbon chain structures each having a first end bonded to a silanol group and a second end bonded to an organic functional group; and
dissolving the precursor compound in the organic solvent,
wherein the organic functional group comprises one of an amine, and epoxide, a carboxyl group, an isocyanate group, a hydroxyl group, or a compound formed from a reaction between two or more of an amine, and epoxide, a carboxyl group, an isocyanate group, a hydroxyl group.

20. The method of claim 19, wherein forming the precursor compound further comprises forming carbon chain structures that comprise:
a carbon number that is between 10 and 1000; and
a hydrogen to carbon ratio H/C that is greater than 2.
